(19) United States
(12) Patent Application Publication
(10) Pub. No.: US 2014/0312988 A1
(43) Pub. Date: Oct. 23, 2014

(54) KA-BAND HIGH POWER AMPLIFIER STRUCTURE HAVING MINIMUM PROCESSING AND ASSEMBLING ERRORS

(71) Applicant: XMW INC., Daejeon (KR)

(72) Inventor: Moohong Lee, Daejeon (KR)

(21) Appl. No.: 14/358,086

(22) PCT Filed: Oct. 4, 2012
(86) PCT No.: PCT/KR2012/008006

§ 371 Date: May 14, 2014

(30) Foreign Application Priority Data
Sep. 21, 2012 (KR) 10-2012-0104848

(51) Int. Cl. H01P 5/12; H03F 3/21

(52) U.S. Cl. CPC H03F 3/211; H03F 2203/21106
USPC 333/137; 330/295

(57) ABSTRACT

A Ka-band high power amplifier structure having minimum processing and assembling errors, which uses a technique in which input and output waveguide flanges of individual amplifiers which are connected in parallel are connected to a waveguide divider and a waveguide combiner from above, and uses a waveguide transition patch implemented on an interconnect substrate for coupling to the individual amplifier to avoid the use of an input and output connector pin and an interconnector.

### TECHNICAL FIELD

The present invention relates, in general, to a Ka-band high-power amplifier structure having a minimum processing and assembly error and, more particularly, to a Ka-band high-power amplifier structure having a minimum processing and assembly error, which provides a high-power amplifier used in a satellite communication base station that sends signals in a Ka-band ranging from 20 to 40 GHz.

### BACKGROUND ART

As shown in FIG. 1, to send an intended low-frequency modem signal from a satellite communication earth station to a satellite involves amplifying an intermediate frequency (IF)-band (1 to 2 G Hz) signal using an amplifier 101, converting the signal into a higher frequency using a mixer 102 and a local oscillator 104, removing unnecessary frequencies using a filter, and then sending the signal to a post amplifier 105.

The signal is amplified using a gain amplifier 106 having high gain in order to send the signal with high power through an antenna, and then is amplified using a drive amplifier 107 for the purpose of high-power amplification.

Afterwards, the signal is divided using a divider 108, and power amplification is performed using individual power amplifiers 109 and 110. A high-power signal is produced by combining output signals using a signal combiner 111

A satellite communication frequency is typically used in C-band (3 to 7 GHz band), X-band (7 to 9 GHz band), Ku-band (12 to 15 GHz band) or Ka-band (20 to 30 GHz band). Since the wavelength of the satellite communication frequency is smaller than the IF signal that is the signal at the front end of the mixer 102, there are a lot of difficulties in designing and constructing a circuit, which is problematic.

In general, in a mobile communication transceiver using 1 GHz band, the wavelength of a signal is about 30 cm. The size of parts is smaller than the size of the wavelength, and there are few parasitic components, such as inductance and capacitance. Thus, active parts of the amplifier are provided in a package.

However, at a high frequency of 20 GHz or higher, as of the Ka-band, the signal to be processed has a small wavelength of about 1.5 cm, and there are a variety of undesirable parasitic components. In order to reduce these undesirable parasitic components, the parts are reduced in size and are sold in the shape of bare chips instead of being sold in a package. Thus, a circuit is constructed using the bare chips and a thin film substrate. As the part size is reduced, it is difficult to produce large power from a single part. In order to produce large power, several same parts are connected in parallel and their outputs are combined.

If heat generated from the power amplified by small parts is not properly discharged outward, the power of the parts is consequently reduced. Furthermore, since the wavelength of the signal processed by the parts is short, the signal is considerably sensitive to external noises. In most cases, the intended circuit is placed in an enclosed metal case which is configured to isolate the inside from the outside. Since the wavelength of the signal is short, if the inner size of the case is erroneously designed, oscillation occurs, which is problematic. In fabrication of the high-power amplifier 105 shown in FIG. 1, which operates in the Ka-band, several bear chip transistors or monolithic microwave integrated circuits (MMICs) are attached in series or parallel to one substrate. In this case, it is difficult to measure the characteristics of individual parts. When one part malfunctions, the substrate to which the parts are attached is heated on a hot plate in order to detach the malfunctioning part from the substrate. However, this may cause the attached state of the other parts to become loose, which is problematic.

In order to solve this problem, as shown in FIG. 2, small structures, referred to as carriers 208, 217 and 223, are provided. Substrates 206, 216 and 221, bare chips 207, 220 and 224, and substrates 209, 218 and 222 are sequentially attached to the carriers 208, 217 and 223 by means of an adhesive such as epoxy resin.

Several carriers 208, 217 and 223 which are constructed in this manner are arranged in series or parallel, and then are fixed to the bottom of the case with bolts, thereby constructing an intended amplifier.

However, when the several carriers 208, 217 and 223 are commonly placed in one case 201, oscillation is inevitable. Thus, several small compartments 232 and 233 are defined in the case, and the carriers 208, 217 and 223 to which the parts are assembled are placed in the compartments 232 and 233. Small holes are formed through the wall between the adjacent rooms, and small substrates 204, 211 and 227, referred to as interconnects, are prepared with a size corresponding to the thickness of the wall and are attached to the bottom of the small holes such that the substrates 204, 211 and 227 extend through the small holes.

In the case of parallel structure, a substrate 213 that forms an input divider and a substrate 223 that forms an output combiner are attached directly to the amplifier case by means of epoxy resin.

Finally, an amplifier input connector pin 202 is connected to the substrate 206 of the carrier 208. Since it is difficult to directly assemble the amplifier input connector pin 202 to the substrate 206, a small interconnect substrate 204 is attached to the front of the carriers 208, 217 and 223. Likewise, it is difficult to directly attach a connector pin 229 of an output waveguide terminal 231 to an output combiner substrate 226. A small interconnect substrate 227 is placed between the connector pin 229 and the output combiner substrate 226.

Afterwards, the carriers, the interconnects and input/output combiner substrates are connected to each other with gold ribbons 203, 205, 210, 212, 214, 215, 219, 225, 228 and 229. Since the amplifier case, the carriers, the substrates on the carriers and the interconnects have processing errors, the distances between objects that are to be connected with the gold ribbons, and the lengths of the gold ribbons also differ from each other.

In addition, the amplifier case, the carriers and the interconnect substrates have different coefficients of thermal expansion. When the temperature of the atmosphere significantly changes in the range from −40 to +80°, the distances between objects that are to be connected may increase. Therefore, the gold ribbons acting as connecting members are given marginal lengths for the purpose of stress relief.

Therefore, in the amplifier case 201 in which a plurality of carriers are connected in series or parallel in order to obtain high gain or high power, the accumulation of different lengths of the gold ribbons that connect the substrates and the carriers serves to attenuate signals. In the case of the parallel structure, this causes an imbalance in amplitudes and phases of two parallel signals.

In addition, the gold ribbons have an effect on the circuit performance by providing an inductance component. Therefore, it is required to reduce the number of the gold ribbons that connect the substrates in order to realize high power from the high-power amplifier 201.

In the high-power amplifier, when heat generated from final devices that amplify output power is not rapidly discharged, the temperature of amplifier devices grows and the amplification performance is deteriorated. Therefore, there is required a specific solution to efficiently dissipate as much heat as possible from the small amplifier devices in order to prevent temperature growth.

### RELATED ART DOCUMENT

1. INTERACTION CIRCUIT FOR MILLIMETER WAVE HIGH POWER AMPLIFIER (Korean Patent Application No. 10-2001-0018345)

2. HIGH-POWER AMPLIFICATION OF SATELLITE COMMUNICATION SYSTEM (Korean Patent Application No. 10-1996-0078517)

3. APPARATUS AND METHOD FOR REAL TIME DETERMINATION OF HIGH POWER AMPLIFIER'S OUTPUT POWER LEVEL AND IT'S OPERATING POINT IN SATELLITE COMMUNICATION (Korean Patent Application No. 10-2004-0023091)

### DISCLOSURE

### Technical Problem

Accordingly, the present invention has been made keeping in mind the above problems occurring in the prior art, and an object of the present invention is to provide a Ka-band high-power amplifier structure having a minimum processing and assembly error, the design of which can solve problems of assembly errors and heat dissipation that are inevitable involving the fabrication of a microwave high-power amplifier. It is therefore possible to produce an intended level of output power as designed, thereby lowering the grade of required amplifier devices.

Another object of the present invention is to provide a Ka-band high-power amplifier structure having a minimum processing and assembly error, which can reduce the consumption of DC power due to less heat generation, and significantly reduce the fabrication cost of an amplifier by reducing the size of an amplifier case.

The features of the present invention are not limited to the foregoing objects, and they are also applied to the amplifiers using packaged parts assembled on Printed circuit boards (PCBs), and the foregoing and other features of the present invention will be apparent to a person skilled in the art from the following description.

### Technical Solution

In order to accomplish the above object(s), an embodiment of the present invention provides a Ka-band high-power amplifier structure having a minimum processing and assembly error. In the high-power amplifier structure, a waveguide divider and a waveguide combiner are coupled from above to input and output waveguide flanges of individual amplifiers which are connected in parallel, and connections to the individual amplifiers include waveguide transition patches formed on interconnect substrates, whereby uses of input/output connector pins and interconnects are precluded, and are.

Another embodiment of the present invention provides a high-power amplifier structure having a minimum processing and assembly error, in which the individual amplifiers include individual amplifier cases which are independent from each other, wherein carriers are attached directly to respective interiors of the amplifier cases

A further embodiment of the present invention provides a high-power amplifier structure having a minimum processing and assembly error, in which the carriers are respectively fixed to respective interiors the amplifier cases with bolts, the individual amplifiers respectively including drive amplifiers which are respectively attached to the carriers, and wherein the individual amplifiers respectively include final amplifiers which are attached directly to the respective amplifier cases by means of epoxy resin.

Further another embodiment of the present invention provides a high-power amplifier structure having a minimum processing and assembly error, in which a signal path is diverged in an E-plane direction, and input waveguide portions connected to the respective amplifiers of the waveguide combiner are bent perpendicularly downward at an angle of 90 degrees, such that input waveguide flanges are attached from above to the respective amplifiers, in order to facilitate heat dissipation from the individual amplifiers.

Another embodiment of the present invention provides a high-power amplifier structure having a minimum processing and assembly error, in which, in a parallel structure of the individual amplifiers, signals are fed between the waveguide divider and the waveguide combiner via the waveguide transition patches.

A further embodiment of the present invention provides a high-power amplifier structure having a minimum processing and assembly error, one individual amplifier of the individual amplifiers that have individual paths in the parallel structure comprises a phase control circuit in order to compensate for combining loss in the waveguide combiner caused by an imbalance in sizes and phases of signals.

Further another embodiment of the present invention provides a high-power amplifier structure having a minimum processing and assembly error, in which the parallel structure includes the drive amplifiers in order to reduce the number of gold ribbons that are necessary when the drive amplifiers are disposed outside the parallel structure.

### DESCRIPTION OF DRAWINGS

FIG. 1 is a block diagram showing a conventional radio transmitter;

FIG. 2 is a view showing the configuration of a conventional microwave high-power amplifier;

FIG. 3 is a view showing the configuration of a Ka-band high-power amplifier having a minimum processing and assembly error according to an embodiment of the present invention;

FIG. 4 is a view showing the combining structure of a waveguide combiner of a Ka-band high-power amplifier having a minimum processing and assembly error according to an embodiment of the present invention; and

FIG. 5 is a view showing the exterior of a final design of a Ka-band high-power amplifier having a minimum processing and assembly error according to an embodiment of the present invention.

### DESCRIPTION OF THE REFERENCE NUMERALS IN THE DRAWINGS

101: amplifier

102: mixer

103: filter

104: local oscillator

105: amplifier

107: drive amplifier

109: output amplifier

202: connector

203: gold ribbon

206: substrate

207: bare chip

208: carrier

301: waveguide input

302: input combiner

303, 310, 315, 322: waveguide transition patch

401: waveguide combiner

402: waveguide flange

410: heat sink

501: amplifier case

502: input waveguide divider

### Mode for Invention

Reference will now be made in greater detail to the present invention, exemplary embodiments of which are illustrated in the accompanying drawings. In the following description of the present invention, detailed descriptions of known functions and components incorporated herein will be omitted when they may make the subject matter of the present invention unclear.

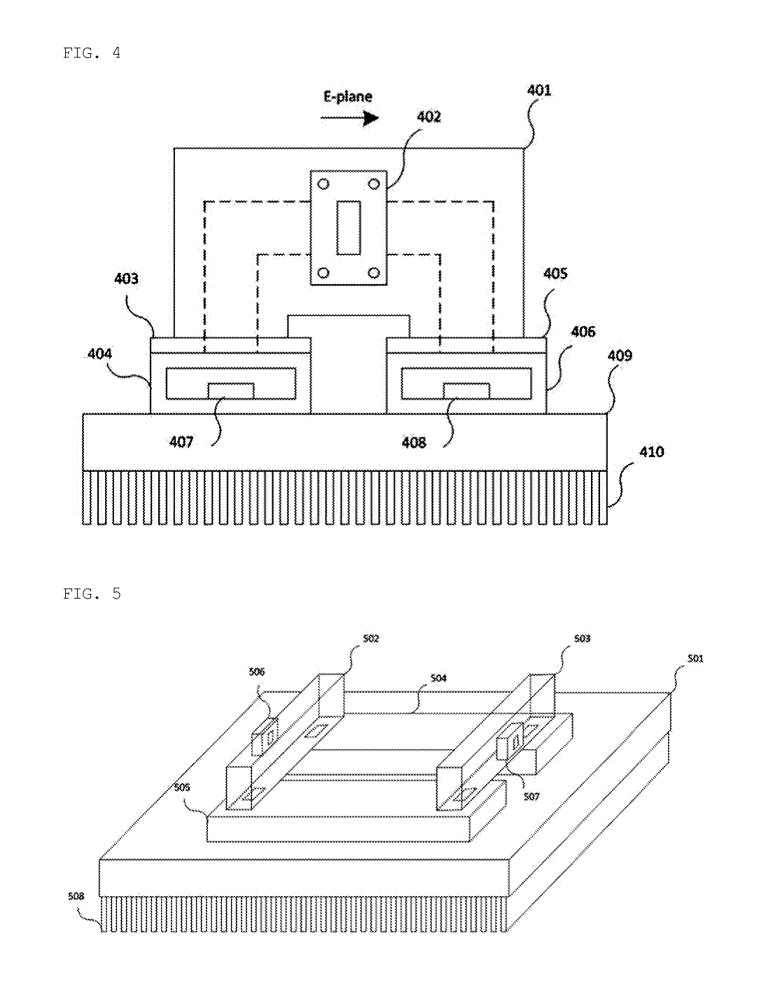

FIG. 3 is a view showing the configuration of a Ka-band high-power amplifier having a minimum processing and assembly error according to an embodiment of the present invention, FIG. 4 is a view showing the combining structure of a waveguide combiner of a Ka-band high-power amplifier having a minimum processing and assembly error according to an embodiment of the present invention, and FIG. 5 is a view showing the exterior of a final design of a Ka-band high-power amplifier having a minimum processing and assembly error according to an embodiment of the present invention.

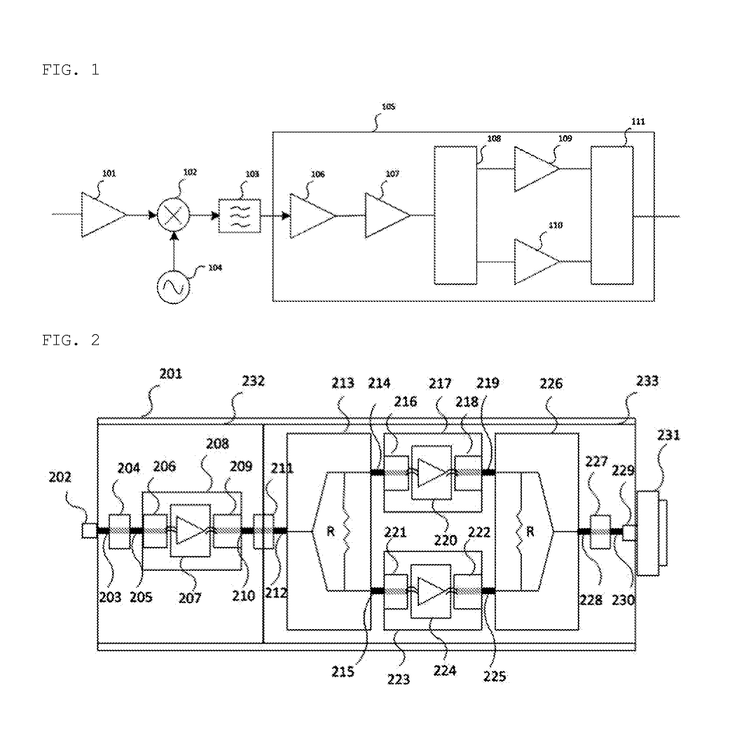

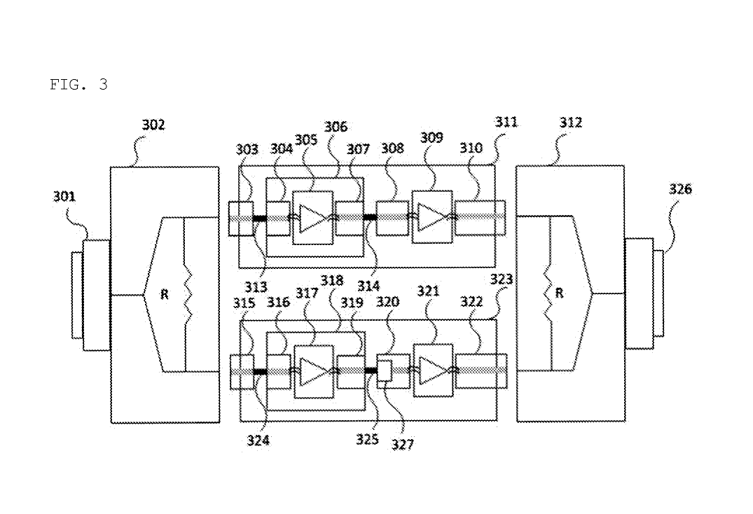

Referring to FIG. 3 to FIG. 5, in order to minimize the number of gold ribbons which connect carriers and interconnects in a high-power amplifier 201 having a parallel structure, as described with reference to FIG. 2, a parallel structure is used between two parallel amplifiers 311 and 323 shown in FIG. 3. An input divider 302 and an output combiner 312 are configured as a waveguide type instead of being a Wilkinson combiner type.

Accordingly, as shown in FIG. 5, the exterior including an input waveguide divider 502 and a waveguide combiner 503 is provided.

In addition, waveguide transition patches 303, 310, 315 and 322 formed on interconnect substrates are used for connection to the individual amplifiers 311 and 323, thereby precluding the use of input/output connector pins and interconnects.

In addition, cases 311 and 323 corresponding to the exteriors of the individual amplifiers 311 and 323 are separately constructed, carriers 306 and 318 to which drive amplifiers 305 and 317 are attached are fixed to the interior of the cases with bolts, and final amplifiers 309 and 321 inside the individual amplifiers 311 and 323 are attached directly to the individual amplifier cases 311 and 323 by means of epoxy resin.

In the case of reworking in which the drive amplifiers 305 and 317 malfunction, the operation is carried out by placing the carriers 306 and 318 to which the drive amplifiers 305 and 317 are attached on a hot plate. In the case of reworking for the final amplifiers 309 and 321, the carriers 306 and 318 are taken out, and the operation can be carried out by respectively placing the cases 311 and 323 to which the final amplifiers 309 and 321 are attached on hot plates.

In addition, a phase control circuit 327 is disposed on one of individual paths in order to minimize the imbalance between the individual paths.

Referring to FIG. 4, in a typical waveguide combiner 401, two input flanges 402 are spaced away from each other in the E-plane direction. As shown in FIG. 4, in order to efficiently dissipate a large amount of heat generated from small high-power amplifier devices 407 and 408, a signal path is diverged in the E-plane direction, and then input waveguide portions connected to the amplifiers of the waveguide combiner 401 are perpendicularly bent again at an angle of 90 degrees. Input waveguide flanges 403 and 405 are attached from above to the top of an amplifier case 409 to which a heat sink 410 is attached such that the input waveguide flanges 403 and 405 are arranged in parallel to each other.

An overall shape of a high-power amplifier according to the present invention is shown in FIG. 5. In the high-power amplifier, individual amplifiers 504 and 504 which emit a large amount of heat are attached directly to the bottom of an amplifier case 501 to which a heat sink 508 is attached in order to efficiently dissipate heat. A waveguide divider 502 and a waveguide combiner 503 are coupled from above to input and output waveguide flanges of the individual amplifiers 504 and 504.

The input waveguide flange 506 and the output waveguide flange 507 of the amplifiers are arranged in the same direction in order to facilitate additional assembly at the system level.

As set forth above, the specific exemplary embodiments of the present invention have been described herein and illustrated in the drawings. Although specific terms are used herein, all such terms are intended to have the same meaning as commonly understood in order to fully convey the concept of the present invention and for better understanding of the present invention, and should not be taken as limiting the scope of the present invention. It is apparent to a person skilled in the art that a variety of other modifications or alterations can be made without departing from the scope of the present invention.

### INDUSTRIAL APPLICABILITY

The Ka-band high-power amplifier structure having a minimum processing assembly error according to an embodiment of the present invention can be designed so as to solve the problems of assembly errors and heat dissipation that are inevitable involving the fabrication of a microwave high-power amplifier. It is therefore possible to produce an intended level of output power as designed, thereby lowering the grade of required amplifier devices.

In addition, the Ka-band high-power amplifier structure having a minimum processing assembly error according to another embodiment of the present invention can reduce the consumption of DC power due to less heat generation, and significantly reduce the fabrication cost of an amplifier by reducing the size of an amplifier case.

1. A Ka-band high-power amplifier structure, wherein a waveguide divider and a waveguide combiner are coupled from above to input and output waveguide flanges of individual amplifiers which are connected in parallel, wherein connections to the individual amplifiers include waveguide transition patches formed on interconnect substrates, whereby uses of input/output connector pins and interconnects are precluded, and processing and assembly errors are minimized.

2. The Ka-band high-power amplifier structure according to claim 1, wherein the individual amplifiers include individual amplifier cases which are independent from each other, wherein carriers are attached directly to respective interiors of the amplifier cases.

3. The Ka-band high-power amplifier structure according to claim 2, wherein the carriers are respectively fixed to respective interiors the amplifier cases with bolts, the individual amplifiers respectively including drive amplifiers which are respectively attached to the carriers, and wherein the individual amplifiers respectively include final amplifiers which are attached directly to the respective amplifier cases by means of epoxy resin.

4. The Ka-band high-power amplifier structure according to claim 3, wherein a signal path is diverged in an E-plane direction, and input waveguide portions connected to the respective amplifiers of the waveguide combiner are bent perpendicularly downward at an angle of 90 degrees, such that input waveguide flanges are attached from above to the respective amplifiers, in order to facilitate heat dissipation from the individual amplifiers.

5. The Ka-band high-power amplifier structure according to claim 4, wherein, in a parallel structure of the individual amplifiers, signals are fed between the waveguide divider and the waveguide combiner via the waveguide transition patches.

6. The Ka-band high-power amplifier structure according to claim 5, wherein one individual amplifier of the individual amplifiers that have individual paths in the parallel structure comprises a phase control circuit in order to compensate for combining loss in the waveguide combiner caused by an imbalance in amplitudes and phases of signals.

7. The Ka-band high-power amplifier structure according to claim 6, wherein the parallel structure includes the drive amplifiers in order to reduce the number of gold ribbons that are necessary when the drive amplifiers are disposed outside the parallel structure.
